(19) United States
(12) Patent Application Publication
(10) Pub. No.: US 2019/0386230 A1
(43) Pub. Date: Dec. 19, 2019

(54) FLEXIBLE DISPLAY DEVICE

(71) Applicant: Wuhan China Star Optoelectronics Technology Co., Ltd., Wuhan, Hubei (CN)

(72) Inventor: Yuejun TANG, Wuhan, Hubei (CN)

(21) Appl. No.: 15/579,161

(22) PCT Filed: Nov. 14, 2017
(86) PCT No.: PCT/CN2017/110855

§ 371 Date: Dec. 1, 2017

(30) Foreign Application Priority Data
Nov. 2, 2017 (CN) 201711061676.1

(51) Int. Cl. H01L 51/00; H01L 51/52; H01L 27/32

(52) U.S. Cl. CPC H01L 51/0097; H01L 51/5253; H01L 2251/5338; H01L 2251/5307; H01L 2251/5315; H01L 27/3276

(57) ABSTRACT

The disclosure provides a flexible display device, including: a flexible substrate, including a display area; and a first frame area, a second frame area, a third frame area and a fourth frame area located at the four sides of the display area, the first frame area and the fourth frame area being opposite to each other, and the second frame area and the third frame area being opposite to each other, a bent line arranged in the second frame area and the third frame area; an organic light emitting layer arranged on the display area; a packaging layer arranged on the organic light emitting layer, the first frame area, the second frame area, the third frame area and the fourth frame area; wherein the flexible substrate and the packaging layer are bent upwards or downwards along the bent lines arranged in the second frame area and the third frame area.

### RELATED APPLICATIONS

The present application is a National Phase of International Application Number PCT/CN2017/110855, filed Nov. 14, 2017, and claims the priority of China Application No. 201711061676.1, filed Nov. 2, 2017.

### FIELD OF THE DISCLOSURE

The disclosure relates to a display technical field, and more particularly to a flexible display device.

### BACKGROUND

Currently, it is paid more attention on an organic light emitting diode (OLED) display as a display device for displaying images. Different from a liquid crystal display (LCD), an OLED display has a self-illumination property and does not adopt a separate light source. Therefore the OLED display may be made thinner and lighter than a display device adopting a separate light source, and may be relatively easier to achieve some features of flexibility and foldable display. In addition, the OLED display has high quality characteristics, such as low power consumption, high brightness, high response speed and the like.

However, the organic light emitting device is susceptible to deteriorations caused by internal factors (such as deterioration caused by an electrode and a light emitting layer caused by oxygen gases, and deterioration caused by a reaction between the light emitting layer and an interface), and deteriorations caused by external factors (such as external moisture, oxygen, UV and manufacturing conditions). In particular, a packaging of an organic light emitting display is very important due to the deadly influence of external oxygen and moisture on the life of the device. In particular, a thin-film packaging is generally adopted in a flexible OLED display. Considering requirements on packaging strength during bending of the flexible display, a package edge and a frame width of a display should meet certain requirements.

### SUMMARY

Based on the above problem, an object of the disclosure is to provide a flexible display device, so as to improve the packaging strength and simultaneously achieve a narrow frame.

According to an aspect of the disclosure, a flexible display device is provided, including: a flexible substrate, including a display area; and a first frame area, a second frame area, a third frame area and a fourth frame area located at the four sides of the display area, the first frame area and the fourth frame area being opposite to each other, and the second frame area and the third frame area being opposite to each other, a bent line arranged in the second frame area and the third frame area; an organic light emitting layer arranged on the display area; a packaging layer arranged on the organic light emitting layer, the first frame area, the second frame area, the third frame area and the fourth frame area; wherein the flexible substrate and the packaging layer are bent upwards or downwards along the bent lines arranged in the second frame area and the third frame area.

Further, bent lines are arranged in the fourth display area, the flexible substrate and the packaging layer are bent upwards or downwards along the bent lines arranged in the fourth frame area.

Further, when the organic light emitting layer is a bottom-emitting organic light emitting layer, the flexible substrate and the packaging layer are bent upwards along the bent lines arranged in the second frame area and the third frame area, an edge of the bent packaging layer and an edge of the flexible substrate are sequentially located above an edge of the organic light emitting layer, and a projection of an edge of the bent packaging layer and an edge of the flexible substrate on the organic light emitting layer are located within the edge of the organic light emitting layer.

Further, when the organic light emitting layer is a top-emitting organic light emitting layer, the flexible substrate and the packaging layer are bent upwards along the bent lines arranged in the second frame area and the third frame area, an edge of the bent packaging layer and an edge of the flexible substrate are sequentially located beneath an edge of the organic light emitting layer, and a projection of an edge of the bent packaging layer and an edge of the flexible substrate on the organic light emitting layer are located within the edge of the organic light emitting layer.

Further, when the organic light emitting layer is a bottom-emitting organic light emitting layer, the flexible substrate and the packaging layer are bent upwards along the bent lines arranged in the second frame area, the third frame area and the fourth frame area, an edge of the bent packaging layer and an edge of the flexible substrate are sequentially located above an edge of the organic light emitting layer, and a projection of an edge of the bent packaging layer and an edge of the flexible substrate on the organic light emitting layer are located within the edge of the organic light emitting layer.

Further, when the organic light emitting layer is a top-emitting organic light emitting layer, the flexible substrate and the packaging layer are bent upwards along the bent lines arranged in the second frame area, the third frame area and the fourth frame area, an edge of the bent packaging layer and an edge of the flexible substrate are sequentially located beneath an edge of the organic light emitting layer, and a projection of an edge of the bent packaging layer and an edge of the flexible substrate on the organic light emitting layer are located within the edge of the organic light emitting layer.

Further, the flexible display device further includes a bonding terminal arranged between the packaging layer and the first frame area, and the bonding terminal is connected with an external controlling circuit; wherein the flexible display device further includes circuits and wirings respectively arranged between the packaging layer and the second frame and between the packaging layer and the third frame, and the circuits and the wirings are located inside the bent line or outside the bent line, and the circuits is connected to the bonding terminal through the wirings.

Further, the flexible display device further includes a bonding terminal arranged between the packaging layer and the first frame area, and the bonding terminal is connected with an external controlling circuit; and the flexible display device further includes circuits and wirings respectively arranged between the packaging layer and the second frame, between the packaging layer and the third frame, and between the packaging layer and the fourth frame, and the circuits and the wirings are located inside the bent line or outside the bent lines, and the circuits is connected to the bonding terminal through the wirings.

Further, the organic light emitting layer is connected to the circuits through the connecting wiring, and the connecting wiring is arranged to be a bent wiring or to be widened or to be divided into at least two branched wirings connected to the same end of the circuit.

Further, the edge of the bent packaging layer and the edge of the bent flexible substrate are located outside the edge of the organic light emitting layer, or, the edge of the bent packaging layer and the edge of the bent flexible substrate vertically align with the edge of the organic light emitting layer.

According to the advantages of the disclosure, the packaging strength of an organic electroluminescence layer is improved by bending the packaging layer and the flexible substrate according to the disclosure, thereby improves the properties of a resistance to moisture and oxygen of the organic electroluminescence layer to further extend the life of the display device. In addition, a width of the frame after the bending of the packaging layer may be narrowed, so as to achieve the object of a narrow frame display.

### BRIEF DESCRIPTION OF THE DRAWINGS

The above and other aspects, features, and advantages of the embodiments of the present disclosure will become more clear from the following description in conjunction with the accompanying drawings, in the drawings:

FIG. 1 is a top view of a flexible display device before bending according to an embodiment of the disclosure;

FIG. 2 is a side view of a flexible display device before bending according to an embodiment of the disclosure;

FIG. 3 is a top view of a flexible display device before bending according to another embodiment of the disclosure;

FIG. 4 is a side view of a flexible display device as shown in FIG.1 after bending;

FIG. 5 is a side view of a flexible display device after bending according to another embodiment of the disclosure;

FIG. 6 is a side view of a flexible display device after bending according to another embodiment of the disclosure;

FIG. 7 is a side view of a flexible display device after bending according to another embodiment of the disclosure;

FIG. 8 is a side view of a flexible display device after bending according to another embodiment of the disclosure;

FIG. 9 is a side view of a flexible display device after bending according to another embodiment of the disclosure;

FIG. 10 is a top view of a flexible display device before bending according to another embodiment of the disclosure;

FIG. 11 is a side view of a flexible display device as shown in FIG. 10 after bending.

### DETAILED DESCRIPTION OF PREFERRED EMBODIMENTS

Hereinafter, embodiments of the present disclosure will be described in details with reference to the accompanying drawings. However, the disclosure may be implemented in many different forms and should not be construed as limited to the specific embodiments set forth herein. Rather, these embodiments are provided to explain the principles of the disclosure and its practical application, thereby enable those skilled in the field to understand various embodiments of the disclosure and various modifications suitable to the particular application contemplated.

In the drawings, in order to be clear, the thickness of the layer and the area may be exaggerated. Like reference signs in the whole specification and the drawings indicate like components.

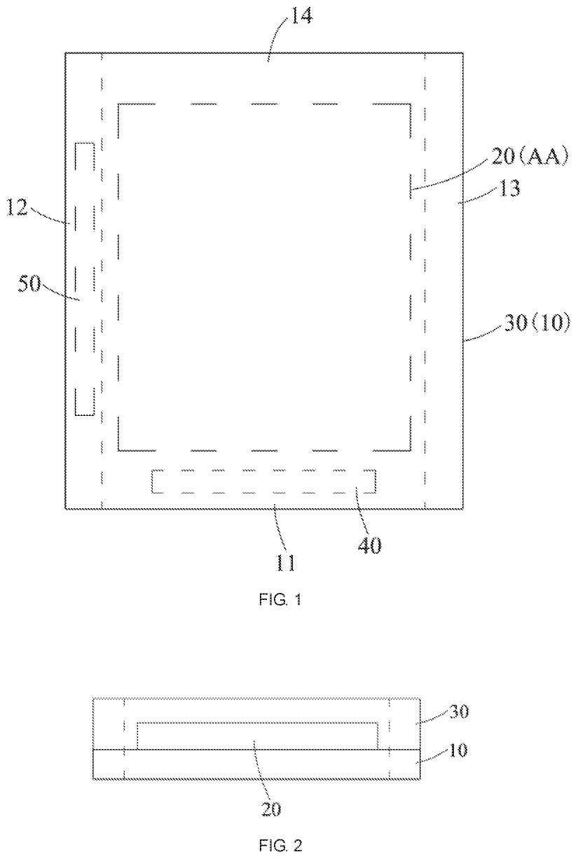

FIG. 1 is a top view of a flexible display device before bending according to an embodiment of the disclosure. FIG. 2 is a side view of a flexible display device before bending according to an embodiment of the disclosure;

Refer to FIGS. 1 and 2, the flexible display device according to an embodiment of the disclosure includes a flexible substrate 10, an organic light emitting layer 20 and a packaging layer 30.

The flexible substrate 10 includes a display area AA, and a first frame area 11, a second frame area 12, a third frame area 13 and a fourth frame area 14 located at the four sides of the display area AA. The first frame area 11 and the fourth frame area 14 are opposite to each other, and the second frame 12 area and the third frame area 13 are opposite to each other. In the embodiment, a bent line (as shown with the dotted line) arranged in the second frame area and the third frame area, but the disclosure is not limited to this. For example, the first frame area 11, the second frame area 12, the third frame area 13 and the fourth frame area 14 are arranged with a greater width.

The flexible substrate 10 may be a thin metal sheet and may be made of polymer materials, such as Polyimide (PI), polycarbonate (PC), polyethersulfone (PES), polyethylene terephthalate (PET), polyethylene naphthalate (PEN), polyarylate Compound (PAR) or glass fiber reinforced plastic (FRP).

The organic light emitting layer 20 is arranged on the display area AA. The organic light emitting layer generally includes a switching layer (having a plurality of thin film transistors), a flat layer, a pixel defining layer, an anode, a luminescent material layer, a cathode, etc.

The packaging layer 30 is arranged on the organic light emitting layer 20, the first frame area 11, the second frame area 12, the third frame area 13 and the fourth frame area 14. In the embodiment, preferably, the packaging layer may be a thin packaging or a cover plate packaging, and the packaging layer may be a thin packaging.

Further, a bonding terminal 40 is arranged between the packaging layer 30 and the first frame area 11, and the bonding terminal 40 is connected with an external controlling circuit. A first circuit and wirings (not shown) are respectively arranged between the packaging layer 30 and the second frame 12. The first circuit 50 and the wirings are both located outside the bent line, and the first circuit 50 is connected to the bonding terminal 40 through the wirings. As another embodiment of the disclosure, the first circuit 50 and the wirings are both located inside the bent line, or, one of the first circuit 50 and the wirings is located outside the bent line and the other one of the first circuit 50 and the wirings is located inside the bent line. The first circuit 50 may include a scan driving circuit and the like, and the wiring may include input signal line of the scan driving circuit and the like.

In addition, the organic light emitting layer 20 is connected to the first circuit 50 through the connecting wiring (not shown). Due to the connecting wiring across the bent line, in order to avoid the bad phenomenon such as breakage and abnormal contact occurring to the connecting wiring, the connecting wiring is arranged to be an inclined wiring or a bent wiring or bold or widened or divided into at least two branched wirings (not shown) connected to the same end of the first circuit 50.

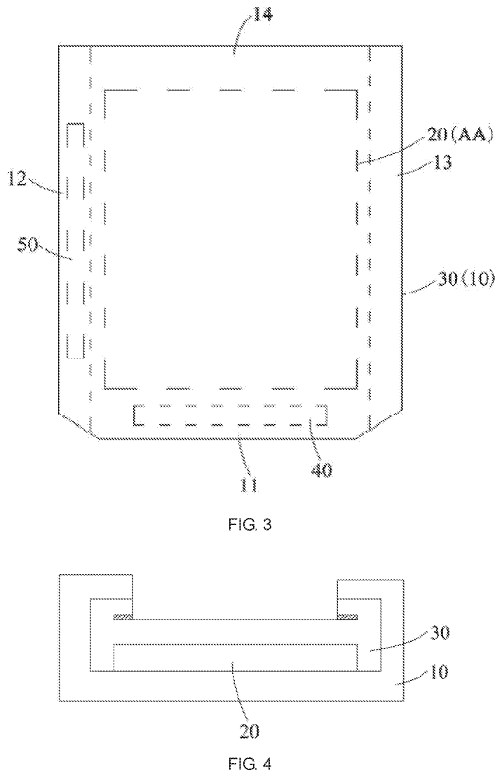

As an embodiment of the disclosure, refer to FIG. 3, the two sides of the first frame have an edging.

FIG. 4 is a side view of a flexible display device as shown in FIG. 1 after bending.

Refer to FIG. 4, the flexible substrate 10 and the packaging layer 30 are bent upwards along the bent lines arranged in the second frame area and third frame area, and the bent packaging layer 30 and the unbent packaging layer 30 are adhered by the adhesive layer (such as an optical adhesive).

In the embodiment, the organic light emitting layer 20 is a bottom-emitting organic light emitting layer, that is, the light emitted by the organic light emitting layer 20 emits from the flexible substrate 10. Under the circumstances, an edge of the bent packaging layer 30 and an edge of the flexible substrate 10 are sequentially located above an edge of the organic light emitting layer 20, and a projection of an edge of the bent packaging layer 30 and an edge of the flexible substrate 10 on the organic light emitting layer 20 are located within the edge of the organic light emitting layer 20. That is, the bent packaging layer 30 and the bent flexible substrate 10 partially overlap with the organic light emitting layer, so as to make the packaging frame to have a width as long as possible, and make the display frame have the characteristics of the narrow frame.

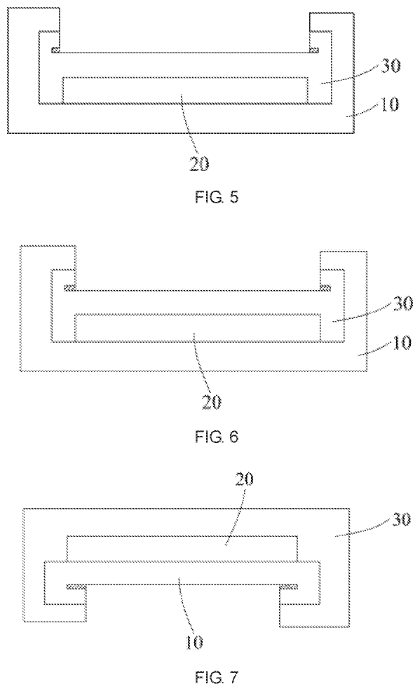

As another embodiment of the disclosure, refer to FIG. 5, an edge of the bent packaging layer 30 and an edge of the flexible substrate 10 are located outside an edge of the organic light emitting layer 20. Under the circumstances, the organic light emitting layer 20 may be a top-emitting organic light emitting layer or a bottom-emitting organic light emitting layer, or, as can be seen from FIG. 6, the edge of the bent packaging layer 30 and the edge of the bent flexible substrate 10 vertically align with the edge of the organic light emitting layer 20. In addition, under the circumstances, the organic light emitting layer 20 may be a top-emitting organic light emitting layer or a bottom-emitting organic light emitting layer.

FIG. 7 is a side view of a flexible display device after bending according to another embodiment of the disclosure.

Refer to FIG. 7, the flexible substrate 10 and the packaging layer 30 are bent downwards along the bent lines arranged in the second frame area and third frame area. And the bent flexible substrate 10 and the unbent flexible substrate 10 are adhered by the adhesive layer (such as the optical adhesive).

In the embodiment, the organic light emitting layer 20 is a top-emitting organic light emitting layer, that is, the light emitted by the organic light emitting layer 20 emits from the packaging layer 30. Under the circumstances, an edge of the flexible substrate 10 and an edge of the bent packaging layer 30 are sequentially located above an edge of the organic light emitting layer 20, and a projection of an edge of the bent packaging layer 30 and an edge of the flexible substrate 10 on the organic light emitting layer 20 are located within the edge of the organic light emitting layer 20. That is, the bent packaging layer 30 and the bent flexible substrate 10 partially overlap with the organic light emitting layer, so as to make the packaging frame to have a width as long as possible, and make the display frame have the characteristics of the narrow frame.

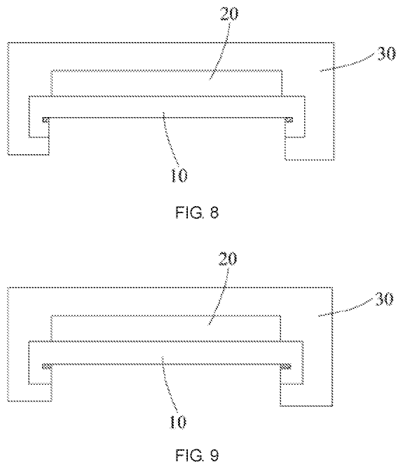

As another embodiment of the disclosure, refer to FIG. 8, an edge of the bent packaging layer 30 and an edge of the flexible substrate 10 are located outside an edge of the organic light emitting layer 20. Under the circumstances, the organic light emitting layer 20 may be a top-emitting organic light emitting layer or a bottom-emitting organic light emitting layer, or, as can be seen from FIG. 9, the edge of the bent packaging layer 30 and the edge of the bent flexible substrate 10 vertically align with the edge of the organic light emitting layer 20. In addition, under the circumstances, the organic light emitting layer 20 may be a top-emitting organic light emitting layer or a bottom-emitting organic light emitting layer.

As another embodiment of the disclosure, the flexible substrate 10 and the packaging layer 30 are bent upwards along the bent lines arranged in the second frame area 12 and the flexible substrate 10 and the packaging layer 30 are bent downwards along the bent lines arranged in the third frame area 13, or, the flexible substrate 10 and the packaging layer 30 are bent downwards along the bent lines arranged in the second frame area 12 and the flexible substrate 10 and the packaging layer 30 are bent upwards along the bent lines arranged in the third frame area 13.

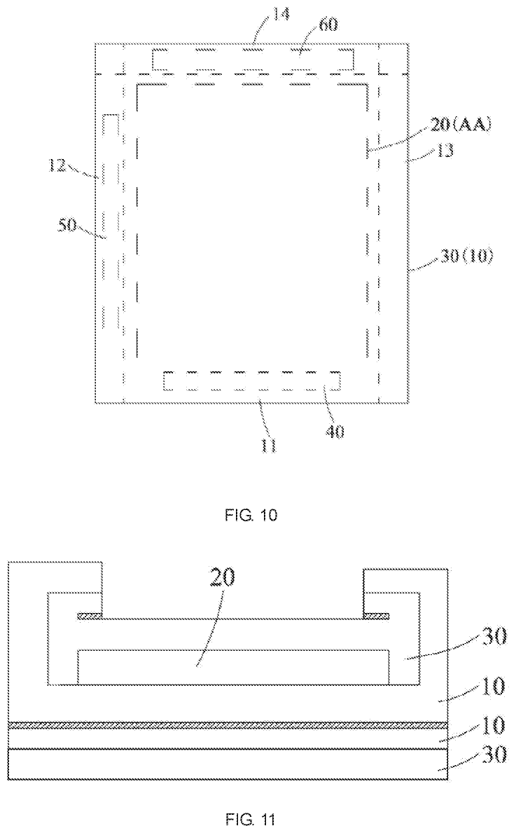

FIG. 10 is a top view of a flexible display device before bending according to another embodiment of the disclosure.

Refer to FIG. 10, a second circuit 60 and wirings (not shown) are respectively arranged between the packaging layer 30 and the fourth frame 14. The second circuit 60 and the wirings are both located outside the bent line, and the second circuit 60 is connected to the bonding terminal 40 through the wirings. As another embodiment of the disclosure, the second circuit 60 and the wirings are both located inside the bent line, or, one of the second circuit 60 and the wirings is located outside the bent line and the other one of the second circuit 60 and the wirings is located inside the bent line. The second circuit 60 may include a data driving circuit, an anti-static circuit and the like, and the wiring may include input signals of the data driving circuit and the like.

FIG. 11 is a side view of a flexible display device as shown in FIG. 10 after bending.

Refer to FIG. 11, the flexible substrate 10 and the packaging layer 30 are bent upwards along the bent lines arranged in the second frame area 12 and third frame area 13. And the bent packaging layer 30 and the unbent packaging layer 30 are adhered by the adhesive layer (such as the optical adhesive); the flexible substrate 10 and the packaging layer 30 are bent downwards along the bent lines arranged in the fourth frame area 14. And the bent flexible substrate 10 and the unbent flexible substrate 10 are adhered by the adhesive layer (such as the optical adhesive).

As another embodiment of the disclosure, the flexible substrate 10 and the packaging layer 30 may be bent upwards along the bent lines arranged in the fourth frame area 14. And the bent packaging layer 30 and the unbent packaging layer 30 are adhered by the adhesive layer (such as the optical adhesive).

In addition, further, as another embodiment of the disclosure, the flexible substrate 10 and the packaging layer 30 may be bent downwards along the bent lines arranged in one or two of the third frame area 13 and the fourth frame area 14. And the bent flexible substrate 10 and the unbent flexible substrate 10 are adhered by the adhesive layer (such as the optical adhesive). Or the flexible substrate 10 and the packaging layer 30 may be bent upwards along the bent lines arranged in the other two or the other one of the second frame area 12, the third frame area 13 and the fourth frame area 14. And the bent packaging layer 30 and the unbent packaging layer 30 are adhered by the adhesive layer (not shown). Or, the flexible substrate 10 and the packaging layer 30 may be bent upwards along the bent lines arranged in the second frame area 12, the third frame area 13 and the fourth frame area 14. And the bent flexible substrate 10 and the unbent flexible substrate 10 are adhered by the adhesive layer (such as the optical adhesive).

In summary, according to the embodiments of the disclosure, packaging strength of the organic electroluminescence layer is improved by bending the packaging layer and the flexible substrate with a frame of greater width, so as to improve the properties of the resistance to moisture and oxygen of the organic electroluminescence layer to further extend the life of the display device. In addition, the width of the frame after the bending of the packaging may be narrowed, so as to achieve the object of a narrow frame display. In the meantime, with the same width of the frame, the display device according to the disclosure has twice the intrusion path of moisture and oxygen at the position of the frame, so as to greatly improve the blocking ability of moisture and oxygen.

Although the present disclosure has been shown and described with reference to specific embodiments, it will be understood by those skilled in the art that various changes in form and details may be made therein without departing from the spirit and scope of the disclosure as defined by the appended claims and their equivalents.

What is claimed is:

1. A flexible display device, comprising:
a flexible substrate, comprising a display area; and a first frame area, a second frame area, a third frame area and a fourth frame area located at four sides of the display area, the first frame area and the fourth frame area being opposite to each other, and the second frame area and the third frame area being opposite to each other, a bent line being arranged in the second frame area and the third frame area;
an organic light emitting layer arranged on the display area; and
a packaging layer arranged on the organic light emitting layer, the first frame area, the second frame area, the third frame area and the fourth frame area;
wherein the flexible substrate and the packaging layer are bent upwards or downwards along the bent lines arranged in the second frame area and the third frame area.

2. The flexible display device according to claim 1, wherein bent lines are arranged in the fourth display area, the flexible substrate and the packaging layer are bent upwards or downwards along the bent lines arranged in the fourth frame area.

3. The flexible display device according to claim 1, wherein when the organic light emitting layer is a bottom-emitting organic light emitting layer, the flexible substrate and the packaging layer are bent upwards along the bent lines arranged in the second frame area and the third frame area, an edge of the bent packaging layer and an edge of the flexible substrate are sequentially located above an edge of the organic light emitting layer, and a projection of an edge of the bent packaging layer and an edge of the flexible substrate on the organic light emitting layer are located within the edge of the organic light emitting layer.

4. The flexible display device according to claim 1, wherein when the organic light emitting layer is a top-emitting organic light emitting layer, the flexible substrate and the packaging layer are bent upwards along the bent lines arranged in the second frame area and the third frame area, an edge of the bent packaging layer and an edge of the flexible substrate are sequentially located beneath an edge of the organic light emitting layer, and a projection of an edge of the bent packaging layer and an edge of the flexible substrate on the organic light emitting layer are located within the edge of the organic light emitting layer.

5. The flexible display device according to claim 2, wherein when the organic light emitting layer is a bottom-emitting organic light emitting layer, the flexible substrate and the packaging layer are bent upwards along the bent lines arranged in the second frame area, the third frame area and the fourth frame area, an edge of the bent packaging layer and an edge of the flexible substrate are sequentially located above an edge of the organic light emitting layer, and a projection of an edge of the bent packaging layer and an edge of the flexible substrate on the organic light emitting layer are located within the edge of the organic light emitting layer.

6. The flexible display device according to claim 2, wherein when the organic light emitting layer is a top-emitting organic light emitting layer, the flexible substrate and the packaging layer are bent upwards along the bent lines arranged in the second frame area, the third frame area and the fourth frame area, an edge of the bent packaging layer and an edge of the flexible substrate are sequentially located beneath an edge of the organic light emitting layer, and a projection of an edge of the bent packaging layer and an edge of the flexible substrate on the organic light emitting layer are located within the edge of the organic light emitting layer.

7. The flexible display device according to claim 1, wherein the flexible display device further comprises a bonding terminal arranged between the packaging layer and the first frame area, and the bonding terminal is connected with an external controlling circuit;
the flexible display device further comprises circuits and wirings respectively arranged between the packaging layer and the second frame and between the packaging layer and the third frame, and the circuits and the wirings are located inside the bent line or outside the bent line, and the circuits is connected to the bonding terminal through the wirings.

8. The flexible display device according to claim 2, wherein the flexible display device further comprises a bonding terminal arranged between the packaging layer and the first frame area, and the bonding terminal is connected with an external controlling circuit;
the flexible display device further comprises circuits and wirings respectively arranged between the packaging layer and the second frame, between the packaging layer and the third frame, and between the packaging layer and the fourth frame, and the circuits and the wirings are located inside the bent line or outside the bent lines, and the circuits is connected to the bonding terminal through the wirings.

9. The flexible display device according to claim 7, wherein the organic light emitting layer is connected to the circuits through the connecting wiring, and the connecting wiring is arranged to be a bent wiring or to be widened or to be divided into at least two branched wirings connected to the same end of the circuit.

10. The flexible display device according to claim 8, wherein the organic light emitting layer is connected to the circuits through the connecting wiring, and the connecting wiring is arranged to be a bent wiring or to be widened or to be divided into at least two branched wirings connected to of the same end of the circuit.

11. The flexible display device according to claim 1, wherein the edge of the bent packaging layer and the edge of the bent flexible substrate are located outside the edge of the organic light emitting layer, or, the edge of the bent packaging layer and the edge of the bent flexible substrate vertically align with the edge of the organic light emitting layer.
